(19) United States
(12) Patent Application Publication
(10) Pub. No.: US 2025/0142816 A1
(43) Pub. Date: May 1, 2025

(54) FLASH MEMORY STRUCTURE

(71) Applicant: UNITED MICROELECTRONICS CORP., Hsin-Chu City (TW)

(72) Inventor: QIULONG WU, Singapore (SG)

(73) Assignee: UNITED MICROELECTRONICS CORP., Hsin-Chu City (TW)

(21) Appl. No.: 18/507,127

(22) Filed: Nov. 13, 2023

(30) Foreign Application Priority Data
Oct. 26, 2023 (TW) 112140943

(51) Int. Cl. H10B 41/20; G11C 5/02; G11C 5/06; H01L 29/423; H10B 41/10

(52) U.S. Cl. CPC H10B 41/20; G11C 5/025; G11C 5/063; H10B 41/10; H10D 30/6892

(57) ABSTRACT

A flash memory structure is provided in the present invention, including an active area and STIs, wherein the diffusion doped region includes a source line doped region extending in a first direction and multiple branch doped regions extending in a second direction at two sides of the source line doped region and alternately arranged along the first direction, and these branch doped regions are isolated by the STIs. An erase gate are on the source line doped region and extends in the first direction, multiple floating gates are on the branch doped regions at two sides of the erase gate, and two word lines respectively at outer sides of the floating gates and extend through multiple branch doped regions in the first direction.

### BACKGROUND OF THE INVENTION

### 1. Field of the Invention

The present invention relates generally to a flash memory structure, and more specifically, to a flash memory structure with alternately arranged branch doped regions.

### 2. Description of the Prior Art

Flash memory is an electronic non-volatile computer storage medium that can be electrically erased and reprogrammed. It is used in a wide variety of commercial and military electronic devices and equipment. To store information, flash memory includes an addressable array of memory cells, typically made from floating gate transistors. Common types of flash memory cells include stacked gate memory cells and split gate memory cells (e.g., the third generation SUPERFLASH (ESF3) memory cell). Split gate memory cells have several advantages over stacked gate memory cells, such as lower power consumption, higher injection efficiency, less susceptibility to short channel effects, and over erase immunity.

The dimension of semiconductor device nowadays keeps scaling down, particularly in the memory device, in order to provide more memory capacity under limited layout area. As the dimension scales down, the spacing between adjacent floating gates in flash memory becomes smaller and smaller, and relevant process window is also reduced. In such circumstances, shallow trench isolations (STIs) responsible for device isolation may not provide proper isolation effect for the devices due to process variation, thus result in the connection and shorting of adjacent floating gates. Accordingly, those of skilled in the art should improve current structure and process for the flash memory, in hope of solving the aforementioned issues.

### SUMMARY OF THE INVENTION

In the light of the aforementioned demand, the present invention hereby provides a novel flash memory structure, with feature of branch doped regions alternately arranged at two sides of source line, to avoid conventional issues like the shorting of adjacent floating gates or the bridging of opposite shallow trench isolations, as well as increase process window and decrease required layout area for memory cell at the same time.

One objective of present invention is to provide a flash memory structure, including a semiconductor substrate with an active area and shallow trench isolations, wherein the active area includes a source line doped region extending in a first direction and multiple branch doped regions extending in a second direction at two sides of the source line doped region and alternately arranged along the first direction, and the branch doped regions are isolated by the shallow trench isolations. An erase gate on the source line doped region and extending in the first direction. Multiple floating gates on the branch doped regions at two sides of the erase gate, and two word lines respectively at outer sides of the floating gates and extending through the multiple branch doped regions in the first direction.

Another objective of present invention is to provide a flash memory structure, including a semiconductor substrate with an active area and shallow trench isolations, wherein the active area includes a source line doped region extending in a first direction and multiple branch doped regions extending in a second direction at two sides of the source line doped region, and the branch doped regions are isolated by the shallow trench isolations. An erase gate on the source line doped region and extending in the first direction, and multiple floating gates on the branch doped regions at two sides of the erase gate, and a first metal layer on the semiconductor substrate, the first metal layer comprises multiple metal line patterns, wherein each metal line pattern is provided with a bending part right on the source line doped region and two straight parts respectively at two ends of the bending part and right on two of the branch doped regions at two sides of the source line doped region and extending in the second direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic layout pattern of a bit cell block of flash memory in accordance with the preferred embodiment of present invention;

FIG. 2 is a schematic cross-sectional view of a flash memory structure in accordance with the preferred embodiment of present invention;

FIG. 3 is an isometric view of a flash memory structure in accordance with the preferred embodiment of present invention;

FIG. 4 is schematic layout pattern including various straps of a flash memory in accordance with the preferred embodiment of present invention;

FIG. 5 is a schematic global layout of a flash memory block in accordance with the preferred embodiment of present invention; and

FIG. 6 is layout pattern of a first metal layer and a second metal layer in various straps of a flash memory in accordance with the preferred embodiment of present invention.

Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). Further, spatially relative terms, such as “beneath,” “below,” “lower,” “above,” “upper,” and the like, may be used herein for ease of description to describe one element or feature relationship to another element(s) or feature(s) as illustrated in the figures.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon (Si), germanium (Ge), gallium arsenide (GaAs), indium phosphide (InP), etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe of combinations features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

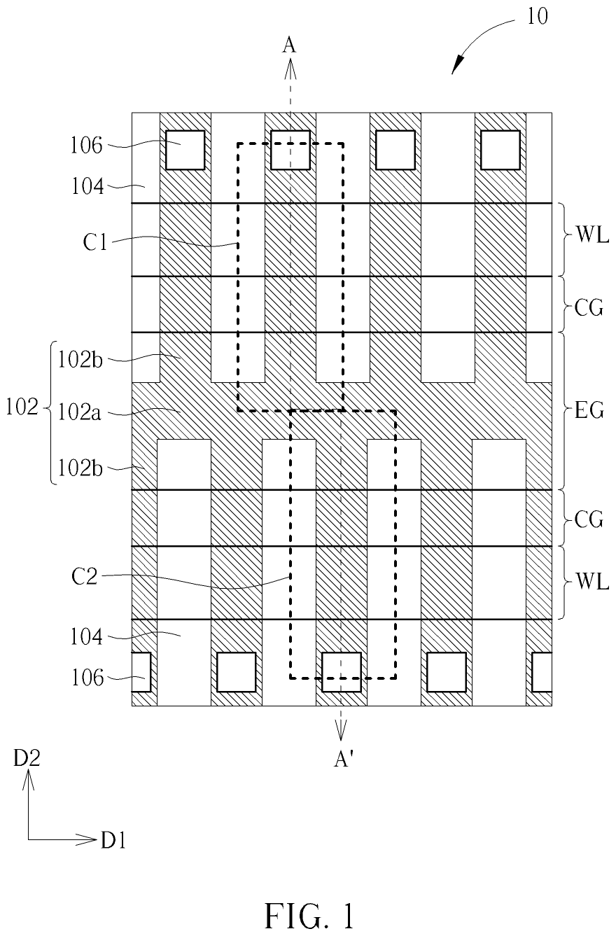

Please refer to FIG. 1, which is a schematic layout pattern of cell block 10 in the flash memory in accordance with the preferred embodiment of present invention, illustrating the layout design of flash memory structure provided by the present invention in FEOL (front-end-of-line) level, such as active areas, erase gate, control gates and word lines. As shown in FIG. 1, the flash memory structure of present invention is provided with an active area 102 and shallow trench isolations (STIs) 104 formed in the semiconductor substrate, wherein active area 102 includes a source line doped region 102a as a main axis extending in a first direction D1 and multiple branch doped regions 102b extending in a second direction D2 and connecting with the source line doped region 102a. The first direction D1 is preferably perpendicular to the second direction D2. Branch doped regions 102b are at two sides of the source line doped region 102a and are alternately arranged along the first direction D1, and adjacent branch doped regions 102b at the same side are isolated by the STIs 104. Accordingly, each branch doped region 102b at one side of the source line doped region 102a is opposite to one STI 104 at the other side of the source line doped region 102a. In the preferred embodiment, the widths of branch doped region 102b and STI 104 in the first direction D1 are the same, but not limited thereto.

Refer still to FIG. 1. In the embodiment of present invention, structures like erase gate EG, control gate CG and word line WL are further provided in FEOL level. As shown in FIG. 1, an erase gate EG is on the source line doped region 102a and extends in the first direction D1. The longitudinal axes of the erase gate EG and source line doped region 102a are preferably aligned, which extend in the first direction D1 and cover parts of the branch doped regions 102b. Two control gates CG are respectively at two sides of the erase gate EG and extend in the first direction D1 through multiple branch doped regions 102b. Two word lines WL are respectively at outer sides of the two control gates CG and extend in the first direction D1 through multiple branch doped regions 102b. In addition, bit line contacts 106 are further set on every branch doped region 102b at further outer sides of the two word lines WL, to electrically connect every branch doped region 102b to bit lines above. In the embodiment of present invention, one branch doped region 102b, including the erase gate EG, control gate CG and word line WL thereon, would correspond to one bit cell, as C1, C2 shown in the figure. It can be seen in the embodiment of present invention that, since opposite branch doped regions 102b are staggered, opposite bit cells C1, C2 are also staggered.

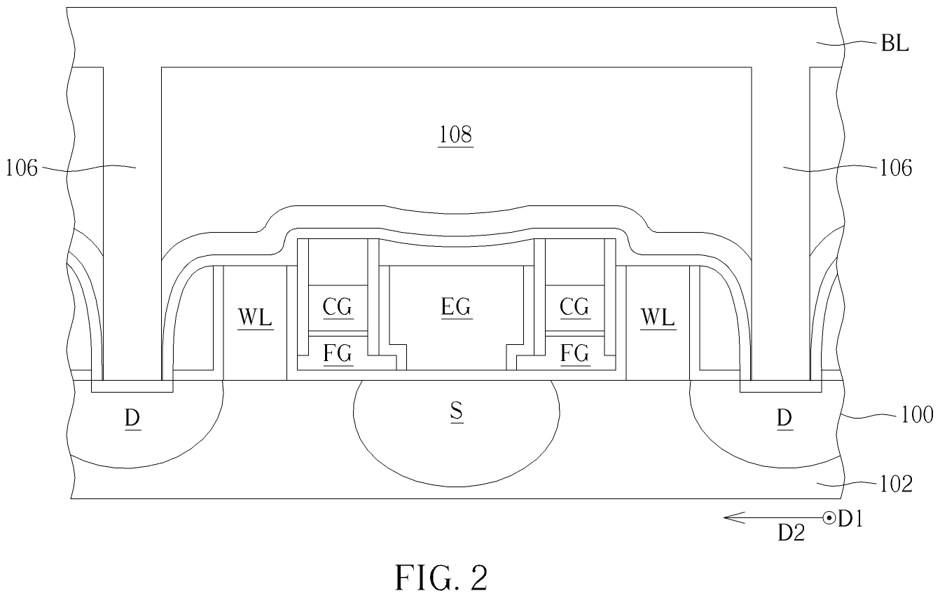

Please refer now to FIG. 2, which is a schematic cross-sectional view of a flash memory structure in accordance with the preferred embodiment of present invention, clearly providing a better understanding for readers about the component arrangement and relative position in a direction vertical to the substrate. FIG. 2 is a cross-sectional view taken along the section line A-A′ in FIG. 1, encompassing a range of two opposite bit cells C1, C2. As shown in FIG. 2, the flash memory of present invention is set on a semiconductor substrate 100. The semiconductor substrate 100 may be a N-type or P-type semiconductor substrate, ex. Si-base bulk substrate or silicon-on-insulator (SOI) substrate, but not limited thereto. The semiconductor substrate 100 shown in the figure corresponds to the active area 102 in FIG. 1, including two opposite and staggered branch doped regions 102b and a source line doped region 102a connecting the two branch doped regions 102b. Doped regions may be formed in the semiconductor substrate 100 through ion implantation process, ex. source (i.e. source line) in the middle of entire memory structure and drains at two sides of the memory structure.

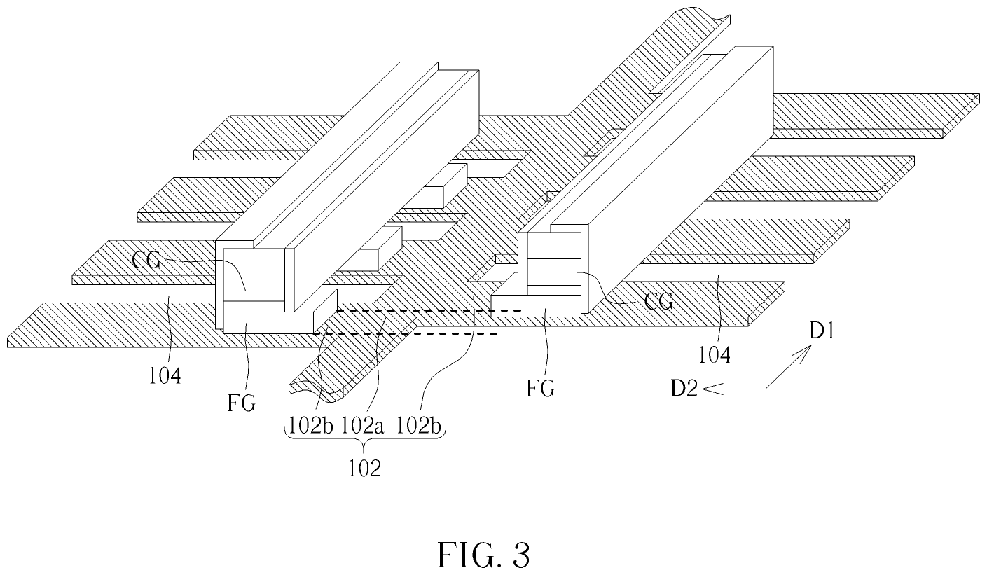

Refer still to FIG. 2. In the embodiment of present invention, erase gate EG is right on the source S, and floating gates FG and control gates CG are set at two sides thereof in the second direction D2, wherein the floating gate FG is on the semiconductor substrate 100, the control gate CG is further on the floating gate FG, and a word line is further provided at outer side of the floating gate FG and control gate CG. In the embodiment of present invention, erase gate EG, source S (i.e. source line), control gate CG and word line WL all extend in the first direction D1 through multiple branch doped regions 102b as shown in FIG. 1. Floating gates FG only locate on the branch doped regions 102b as shown in FIG. 3. The aforementioned components are isolated from each other through dielectric layers or films (ex. silicon oxide layer, undenoted). In the embodiment of present invention, the material of erase gate EG and word line WL may be conductive metal or polysilicon, the material of floating gate FG and control gate CG may be polysilicon, the dielectric layer between floating gate FG and control gate CG may be silicon oxide-silicon nitride-silicon oxide (ONO), and hard mask layer (undenoted) on the control gate CG may be silicon nitride-silicon oxide-silicon nitride (NON). In addition, drain D is set at outer side of the word line WL, which is connected with the bit line BL above through bit line contact 106. The entire memory structure is covered by an interlayer dielectric layer (ILD) 108. Please note that although the control gates CG are provided in the memory structure of present invention, there may be some memory architectures or types without control gate design. The present invention is not limited to the memory with control gate.

Please refer to FIG. 3, which is an isometric view of a flash memory structure in accordance with the preferred embodiment of present invention. Please note that in order to highlight essential components to be described in the figure, erase gate EG and word line WL in the structure are omitted in FIG. 3. In the embodiment of present invention, as shown in FIG. 3, structures at two sides of the source line doped region 102a in the second direction D2 are substantially identical, with only the difference that branch doped regions 102b at two sides are alternately arranged rather than oppositely arranged, so that the branch doped regions 102b at one sides would be opposite to STIs 104 at the other sides. Control gate CG extends in the first direction D1 through multiple branch doped region 102b and the floating gates FG thereon. In conventional skills, if STIs 104 between adjacent floating gates FG are not protruding enough in the second direction D2 toward the source line doped region 102a due to process variation, they may not properly isolate the floating gates and result in the connection and shorting of adjacent floating gates FG at the same side. In another aspect, if this issue is solved by the way of reducing the width of source line doped region 102a (i.e. make the STIs 104 further protruding toward the source line doped region 102a), the STIs 104 may bridges with opposite STIs 104 and cut off the source line doped region 102a, leading to the failure of devices.

The staggered arrangement for the branch doped regions 102b of present invention is that the branch doped regions 102b at one side of the source line doped region 102a are opposite to the STIs 104 at the other side. In this way, even the width of source line doped region 102a is reduced, the STIs 104 at two sides of the source line doped region 102a will not be bridged since they are staggered designedly. In addition, since staggered design can increase process window, the width of source line doped region 102a in the second direction D2 may be further reduced or the neck length of control gate CG to source line doped region 102a may be increased, so as to further reduce the required layout area for bit cell (as C1, C2 shown in FIG. 1), which is another great advantage of the present invention.

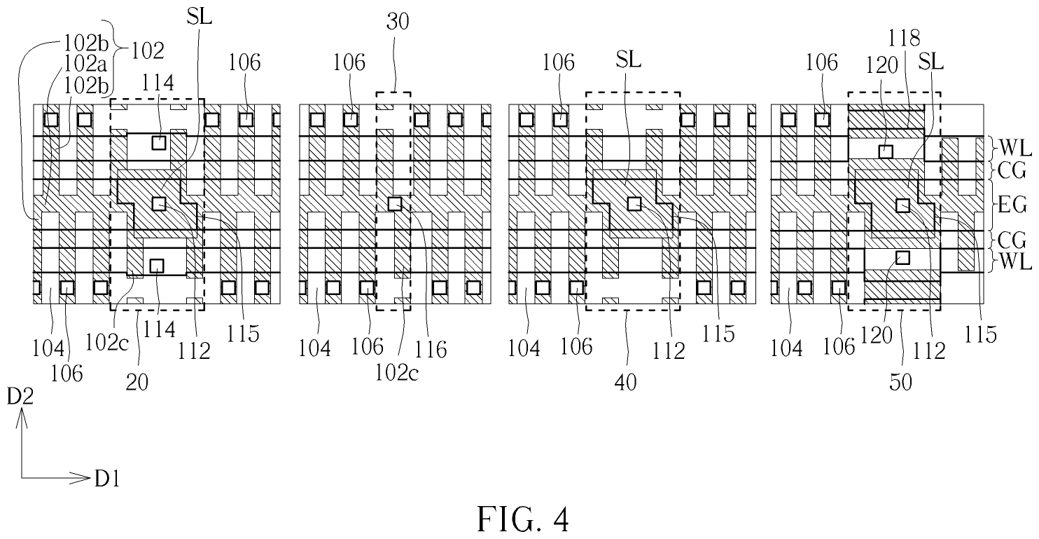

Please refer now to FIG. 4, which includes schematic layout patterns of various straps in FEOL level of the flash memory in accordance with the preferred embodiment of present invention. The layout pattern shown in FIG. 1 is mainly directed at the bit cell block 10 of flash memory, with its layout patterns are all comprised of repeating and alternate branch doped regions 102b with the same length/width. In other constituent regions of the flash memory, ex. strap regions like word line strap 20, erase gate strap 30, source line strap 40 and control gate strap 50 shown in FIG. 4, its layout patterns will be different from the one of bit cell block 10.

First, with regard to the word line strap 20, the word line strap 20 in the embodiment of present invention is designedly for setting word line contacts 114 and source line contacts 112. The word line contact 114 is provided on the position of word line WL in the word line strap 20, which may electrically connect the word line WL to a first metal layer (not shown) above. The portion of word line WL for setting the word line contact 114 may have larger width in the second direction D2 to allow the landing of word line contact 114. The center of word line strap 20 may have a source line contact region SL formed in the semiconductor substrate and connected with the source line doped region 102a and branch doped regions 102c at two sides. The width of source line contact region SL in the second direction D2 is larger than the one of source line doped region 102a, to provide larger landing area for the source line contact 112. The branch doped regions 102c connecting the source line contact region SL may also be staggered, and its length in the second direction D2 is smaller than the one of normal branch doped region 102b, without any bit line contact 106 connected thereon and not function as bit cell. Shorter branch doped region 102c in the present invention may be considered as a dummy pattern. Source line contact region SL is exposed from the opening 115 of erase gate EG, with source line contact 112 formed thereon to electrically connect the source line contact region SL to a first metal layer (not shown) above. The layout of bit cell blocks 10 at two sides of the word line strap 20 have already been disclosed in FIG. 1. Relevant and redundant description will be herein omitted.

Refer still to FIG. 4. With regard to erase gate strap 30, it is designedly for setting the erase gate contacts 116. Erase gate contact 116 is formed on the position of erase gate EG in the erase gate strap 30, which may electrically connect the erase gate EG to a first metal layer (not shown) above. The source line doped region 102a in the erase gate strap 30 is identical to the one in bit cell region, and the branch doped regions 102c therein are also provided with staggered feature, with its length in the second direction D2 smaller than the one of normal branch doped region 102b, without any bit line contact 106 connected thereon and not function as bit cell.

Refer still to FIG. 4. With regard to source line strap 40, it is designedly for setting source line contact 112. The design of source line strap 40 is substantially identical to the one of word line strap 20, with the difference that no word line contact 114 is arranged on the source line strap 40, and merely a source line contact region SL is exposed from the opening 115 of erase gate EG, with a source line contact 112 set thereon to electrically connect the source line contact region SL with a first metal layer (not shown) above.

Refer still to FIG. 4. With regard to control gate strap 50, it is designedly for setting control gate contact 120 and source line contact 112. The control gate CG in the control gate strap 50 is provided with a protruding part 118 extending outwardly in the second direction D2, to provide a larger landing area for control gate contact 120. The control gate contact 120 may electrically connect the control gate CG with a first metal layer (not shown) above. A source line contact region SL is formed in the center of the control gate strap 50 in the semiconductor substrate and is connected with the source line doped regions 102a at two sides, but is not connected with any branch doped region substantially. The width of source line contact region SL in the second direction D2 is larger than the one of source line doped region 102a, to provide larger landing area for source line contact 112. Source line contact region SL is exposed from the opening 115 of erase gate EG, with a source line contact 112 formed thereon to electrically connect the source line contact region SL to a first metal layer (not shown) above. In this embodiment, the branch doped region 102b at one side of the control gate strap 50 functions as a regular bit cell, while the branch doped region 102c at the other side of the control gate strap 50 is dummy pattern.

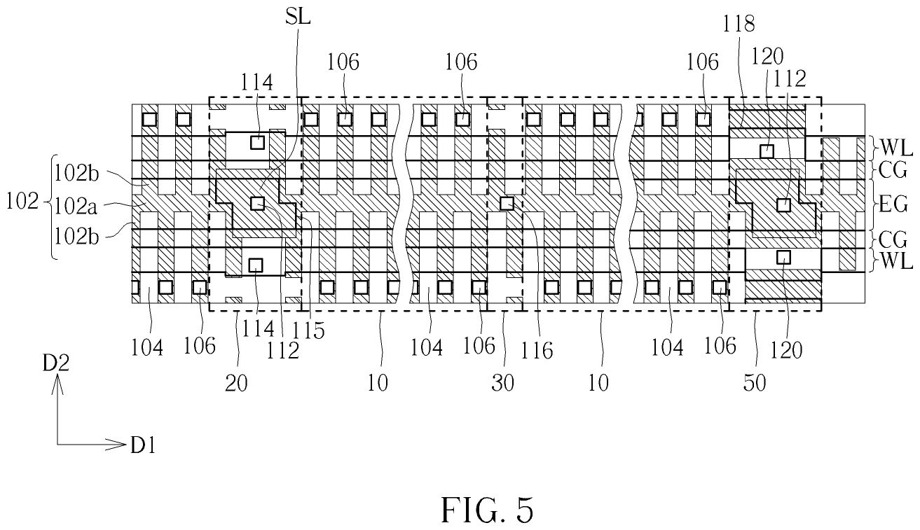

Please refer now to FIG. 5, which is a schematic global layout of a flash memory block in accordance with the preferred embodiment of present invention. The layout pattern of FIG. 5 may be comprised of the aforementioned straps shown in FIG. 4, including bit cell block 10, word line strap 20, erase gate strap 30, control gate strap 50, etc., wherein the erase gate strap 30 is preferably in the middle of bit cell block 10, while word line strap 20 and control gate strap 50 are respectively at two ends of the bit cell block 10. The number of branch doped regions 102b in the bit cell block 10 is not specifically limited, only depending on memory capacity and design of the invention. The bit line contacts 106 on the bit cell block 10 may be shared with other adjacent branch doped regions (not shown) in the second direction D2. Word line WL may be segmented by the protruding part 118 of control gate CG, and erase gate EG may be segmented by the word line strap 20 and the opening of control gate strap 50. Source line contact region SL in the word line strap 20 may be shared with the bit cell blocks 10 at two sides in the first direction D1. The source line contact region SL in the control gate strap 50 is only used by the bit cell blocks 10 at one side in the first direction D1, while the cell block at the other side is just dummy pattern, but not limited thereto. Please note that in the memory architecture without control gate design, the layout pattern of control gate strap 50 will be modified or be replaced with other straps.

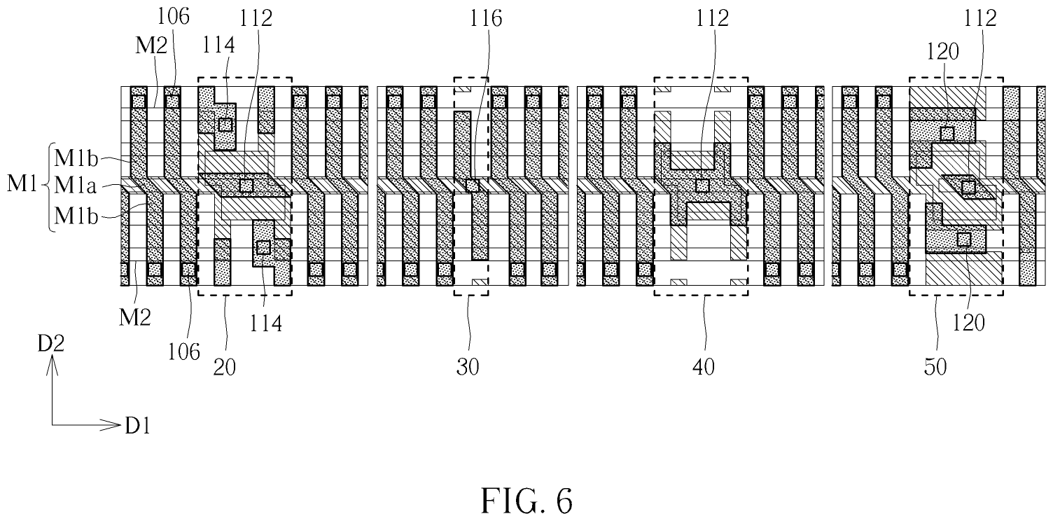

Please refer now to FIG. 6, which includes layout patterns of a first metal layer M1 and a second metal layer M2 of various straps in BEOL (back-end-of-line) level of a flash memory in accordance with the preferred embodiment of present invention. These strap regions may correspond to the straps like word line strap 20, erase gate strap 30, control gate strap 50 in FIG. 4. In the embodiment of present invention, the pattern of first metal layer M1 may be modified in response to the design of staggered branch doped regions in FEOL (front-end-of-line) level. As shown in FIG. 6, the first metal layer M1 includes multiple longitudinal metal line patterns, wherein each metal line pattern is provided with a bending part M1a right above the source line doped region 102a (FIG. 4), in response to the staggered arrangement of branch doped regions. Two straight parts M1b (FIG. 4) are connected respectively with two ends of the bending part M1a, locating right above the two branch doped regions 102b (FIG. 4) at two sides of the source line doped region 102a and extending in the second direction D2. The aforementioned contact structures in FIG. 4, like bit line contact 106, source line contact 112, word line contact 114, erase gate contact 116 and control gate 120, etc., may electrically connect the relevant components in FEOL level to corresponding portions of the first metal layer M1. For example, the bit line contact 106 electrically connects a branch doped region 102b to a straight part M1b of a metal line pattern in the first metal layer M1. In the embodiment of present invention, the patterns of second metal layer M2 is not influenced by the staggered branch doped regions, thus they are all in the form of straight metal patterns without specific bending part M1a like the ones in the first metal layer M1.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A flash memory structure, comprising:
a semiconductor substrate with an active area and shallow trench isolations, wherein said active area comprises a source line doped region extending in a first direction and multiple branch doped regions extending in a second direction at two sides of said source line doped region and alternately arranged along said first direction, and said branch doped regions are isolated by said shallow trench isolations;
an erase gate on said source line doped region and extending in said first direction; and
multiple memory cells, each said memory cell is provided with a floating gate on one said branch doped region at one side of said erase gate.

2. The flash memory structure of claim 1, wherein said branch doped region at one side of said source line doped region corresponds to one said shallow trench isolation at the other side of said source line doped region.

3. The flash memory structure of claim 1, wherein multiple said branch doped regions constitutes a bit cell block, and an erase gate strap is in the middle of said bit cell block.

4. The flash memory structure of claim 3, further comprising two control gates respectively on said floating gates at two sides of said source line doped region and extending in said first direction through multiple said branch doped regions, and one end of said bit cell block is further provided with a control gate strap.

5. The flash memory structure of claim 4, wherein said control gate is provided with a protruding part extending in said second direction on said control gate strap, and said control gate is connected to a first metal layer through a control gate contact on said protruding part.

6. The flash memory structure of claim 3, further comprising two word lines respectively at outer sides of said floating gates and extending in said first direction through multiple said branch doped regions, and one end of said bit cell block is further provided with a word line strap.

7. The flash memory structure of claim 6, wherein said source line doped region is connected to a first metal layer through a source line contact on said word line strap.

8. The flash memory structure of claim 6, wherein said word line is connected to a first metal layer through a word line contact on said word line strap.

9. The flash memory structure of claim 3, wherein said erase gate is connected to a first metal layer through an erase gate contact on said erase gate strap.

10. The flash memory structure of claim 1, further comprising a first metal layer on said semiconductor substrate, said first metal layer comprises multiple metal line patterns, wherein each said metal line pattern is provided with a bending part right above said source line doped region and two straight parts respectively at two ends of said bending part and right above two of said branch doped regions at two sides of said source line doped region and extending in said second direction.

11. The flash memory structure of claim 10, wherein two said straight parts of each said metal line pattern are connected respectively with two said branch doped regions through bit line contacts.

12. A flash memory structure, comprising:
a semiconductor substrate with an active area and shallow trench isolations, wherein said active area comprises a source line doped region extending in a first direction and multiple branch doped regions extending in a second direction at two sides of said source line doped region, and said branch doped regions are isolated by said shallow trench isolations;
an erase gate on said source line doped region and extending in said first direction; and
multiple memory cells, each said memory cell is provide with a floating gate on one said branch doped region at one side of said erase gate; and
a first metal layer on said semiconductor substrate, said first metal layer comprises multiple metal line patterns, wherein each said metal line pattern is provided with a bending part right above said source line doped region and two straight parts respectively at two ends of said bending part right above two of said branch doped regions at two sides of said source line doped region and extending in said second direction.

13. The flash memory structure of claim 12, wherein said multiple branch doped regions at two sides of said source line doped region are alternately arranged along said first direction, and said branch doped region at one side of said source line doped region corresponds to one said shallow trench isolation at the other side of said source line doped region.

14. The flash memory structure of claim 12, wherein multiple said branch doped regions constitutes a bit cell block, and an erase gate strap is in the middle of said bit cell block.

15. The flash memory structure of claim 14, further comprising two control gates respectively at said floating gates at two sides of said source line doped region and extending in said first direction through multiple said branch doped regions, and one end of said bit cell block is further provided with a control gate strap.

16. The flash memory structure of claim 15, wherein said control gate is provided with a protruding part extending in said second direction on said control gate strap, and said control gate is connected to a first metal layer through a control gate contact on said protruding part.

17. The flash memory structure of claim 14, further comprising two word lines respectively at outer sides of said floating gates and extending through said multiple branch doped regions in said first direction, and one end of said bit cell block is further provided with a word line strap.

18. The flash memory structure of claim 17, wherein said source line doped region is connected to a first metal layer through a source line contact on said word line strap.

19. The flash memory structure of claim 14, wherein said erase gate is connected to a first metal layer through an erase gate contact on said erase gate strap.

20. The flash memory structure of claim 14, wherein said word line is connected to said first metal layer through a word line contact on said word line strap.

21. The flash memory structure of claim 11, wherein two said straight parts of each said metal line pattern are connected respectively with two said branch doped regions through bit line contacts.
